(19) United States
(12) Patent Application Publication
(10) Pub. No.: US 2021/0282268 A1
(43) Pub. Date: Sep. 9, 2021

(54) Advanced Manufacturing Method for the Manufacturing of High-Precision Electronic Flexible Circuit Boards enabling the Democratization of design, development, and production of electronic and electrical devices

(71) Applicants: Alexandre Perry Kamel, Centennial, CO (US); Max Myakishev-Rempel, San Diego, CA (US); Jordan Potarf, Centennial, CO (US)

(72) Inventors: Alexandre Perry Kamel, Centennial, CO (US); Max Myakishev-Rempel, San Diego, CA (US); Jordan Potarf, Centennial, CO (US)

(21) Appl. No.: 17/188,016

(22) Filed: Mar. 1, 2021

Related U.S. Application Data
(60) Provisional application No. 63/100,341, filed on Mar. 9, 2020.

(51) Int. Cl. H05K 3/00; H05K 3/26; H05K 3/02; H05K 3/24

(52) U.S. Cl. CPC H05K 3/0082; H05K 3/247; H05K 3/025; H05K 3/26

(57) ABSTRACT

The present invention is a novel method of preparing copper sheeting for exposure to UV or optical light in the process of manufacturing flexible printed circuit boards. This method seeks to remove the need for the highly complex, costly, and capital-intensive use of collimated UV lights and vacuum chambers in conventional FPCB manufacturing by preparing copper sheeting for non-vacuum non-collimated UV exposure with a relatively trivial method using clear vinyl stickers, conventional toner-adhering decorative foil, and UV reflective glue. This in turn will “democratize” the design, development, fabrication, production, and distribution of advanced electronics that depend upon the use of high-precision FPCBs.

### CROSS-REFERENCE TO RELATED APPLICATIONS

This application claims priority under 35 U.S.C. § 119(e) to U.S. Provisional Application Ser. No. 63/100,341, titled “Advanced Manufacturing Methods for Manufacturing of High-Precision Electronic Flexible Circuit Boards enabling Democratization of design, development, and production of electronic and electrical devices,” filed on Mar. 9, 2020, which is hereby incorporated herein by reference in its entirety.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### BACKGROUND

Manufacturing high-precision Flexible Printed Circuit Boards (FPCBs) has historically required highly specialized and costly equipment. The cost and complexity of such equipment and associated manufacturing methods typically puts access and use of such equipment, facilities, and processes (and therefore the ability to design and build high-precision FPCBs) outside the reach of all but large, well-capitalized companies.

FPCBs are generally manufactured, with some variation among different methods, in a series of steps consisting of laminating a photoresist material to copper sheeting, applying an exposure mask to the laminated copper sheeting (whereby the traces and pads representing the desired circuit design is transparent or translucent, and the remaining mask is opaque), exposing the copper sheeting laminated with photoresist material, with the mask applied, to UV light, where such UV light reacts with the photo-sensitive laminate on the copper sheeting, developing the exposed laminated copper sheeting in a solution that removes the un-exposed (covered by opaque portion of exposure mask) laminate, but leaves the exposed laminate, etching the copper laminate in an acid solution (typically a Cupric-Chloride or similar solution), that removes the copper where it is not protected by the exposed laminate, and removing the exposed protective laminate to reveal copper pads and traces (constituting the circuit design).

There are variations on this process, including silk-screening or screen printing of circuit designs onto the laminated copper sheeting, and other such variations; but the overall process consists of similar steps, including printing (or screening), development, etching, and stripping.

Once this process is completed, the copper circuit is then used to assemble and connect various electrical and electronic components to create an electrical or electronic product or circuit.

This conventional methodology requires highly complex and costly equipment to achieve the high levels of precision required for high-precision FPCB production. For example, the mask used during exposure to UV light that allows UV light through transparent traces generally consists of specialized materials like Silver Halide to enable an opaque trace for exposure of the circuit design, with highly opaque surfaces to block UV to avoid exposing those elements that are not part of the intended design. After application of Silver Halide mask, the laminated copper is then exposed to highly collimated UV lighting. This columniation is required to achieve high-precision circuits, because if the UV light strikes the surface of the mask at even a slight angle, it can “smudge” the circuit elements and cause spreading and/or distortion in the circuit features (traces or lines and pads). For this reason, the UV exposure generally consists of highly collimated laser light sources or emitters, and this is quite costly and complex to operate.

Furthermore, in order to reduce the risk of smudging or distortion, the design mask (where the circuit design is transparent or translucent) must be tightly applied to the laminated copper sheeting to avoid or minimize separation between these layers. To minimize this spacing, the conventional process is to expose the laminated copper sheeting (with layers for photo-sensitive laminate and the circuit design mask) in a vacuum chamber (which removes air between layers to ensure a tight fit). Such vacuum chambers are relatively costly and complex to procure and operate.

After such a process (or variation thereof), the exposed material is subjected to what is often called “wet processing” (submerged or processed in solutions of base developer, acid etch, and stripper) as briefly described above.

This conventional process is burdened with a few costly and complex steps that require sophisticated equipment and facilities including the use of specialized masking material, the use of collimated UV laser light sources, and exposure of UV light to the surface of the copper sheeting in a vacuum chamber.

### SUMMARY

The present invention allows FPCB manufacturers to avoid the costly and complex steps of using a specialized masking material, columnated UV laser lights, and vacuum chambers. In one embodiment of the present invention, these highly complex, costly, and capital-intensive processes are replaced with the relatively trivial and simple method of using clear vinyl stickers, conventional decorative foil, and UV reflective sticker glue to prepare copper sheeting for further processing.

The end result of this method is a laminated copper sheet with a sticker that has highly transparent circuit features and highly opaque areas between such features. Furthermore, because of the use of a vinyl sticker, the circuit design mask adheres strongly and closely to the laminated copper.

Because the above-mentioned mask “sticker” is so transparent where circuit design features are, and so opaque elsewhere (due to use of clear vinyl sticker for transparency for circuit design features, and double layer of laser ink and decorative foil elsewhere), and because of the tightness with which the sticker adheres to the surface of the laminated copper, and, finally, because of the UV reflective quality of the glue used in the sticker, there is no need for using UV lasers or other collimated light sources in a vacuum chamber. The reasons are a) the closer adherence of the sticker to the laminated copper sheet reduces the risk of light entering beneath the sticker (or between materials) that would ordinarily blur the circuit features; and b) the use of UV reflective glue reflects any UV light that may enter or seek to enter between the mask and laminated copper surface, further reducing or minimizing the blurring effect. The fact that toner-adhering decorative foil bonds with the pure black ink used on the vinyl sticker (and does not bond elsewhere where the clear circuit traces and pads are placed) ensures that the material is highly opaque where light is not intended to penetrate or pass through the mask.

The combination of these effects eliminates the need for costly and complex collimated laser banks in vacuum exposure chambers while retaining exceptionally high-fidelity in the exposing of the circuit design to the laminated copper sheeting. As a result, the new method will significantly reduce the cost and complexity of producing high-precision FPCBs, allowing FPCB production to be more available and accessible to far more people and organizations.

### BRIEF DESCRIPTION OF THE DRAWINGS

Not Applicable

### DETAILED DESCRIPTION OF THE INVENTION

The terminology used herein is for the purpose of describing particular embodiments only and is not intended to be limiting of the invention. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, elements, components, and/or groups thereof.

Unless otherwise defined, all terms (including technical and scientific terms) used herein have the same meaning as commonly understood by one having ordinary skill in the art to which this invention belongs. It will be further understood that terms, such as those defined in commonly used dictionaries, should be interpreted as having a meaning in the context of relevant art and the present disclosure will not be interpreted in an idealized or overly formal sense unless expressly so defined herein.

In describing the invention, it will be understood that a number of elements are disclosed. Each of these elements has an individual benefit, and each can also be used in conjunction with one or more, or in some cases all, of the other disclosed elements. Accordingly, for the sake of clarity, this description will refrain from repeating every possible combination of elements in an unnecessary fashion. Nevertheless, the specification and claims should be read with the understanding that such combinations are entirely within the scope of the invention and the claim.

In the preferred embodiment of the invention, the method may comprise laminating copper sheeting with a photoresist material.

In the preferred embodiment of the invention, the method may further comprise applying a clear vinyl sticker onto the surface of the photoresist material of the laminated copper sheeting. The clear vinyl sticker has a sticky side that may be placed completely flush to the surface of the photoresist material of the laminated copper sheeting in order to minimize gaps between the sticker and the surface of the laminated copper sheeting. The sticky side of the sticker may be coated with, or be comprised of, an optically reflective glue in order to reflect incidental UV light and other light away from the gaps between the sticker and the surface of the photoresist material of the laminated copper sheeting.

In the preferred embodiment of the invention, the method may further comprise laser printing a circuit design in back ink onto the smooth side of the clear vinyl sticker in the negative (meaning that a circuit's design is not printed, and, therefore, the clear vinyl sticker remains clear in these areas while the negative or surface areas between the circuit's design is printed over with black ink). The circuit design may be comprised of any elements that are meant to remain after the manufacturing process is complete including, but not limited to, traces, lines, pads, and symbols.

In the preferred embodiment of the invention, the method may further comprise hot-laminating toner-adhering decorative foil (often used for the creation of decorative invitations, artwork, or crafts) onto the smooth side of the clear vinyl sticker that has the negative of the circuit design laser printed onto it in black ink, wherein the toner-adhering decorative foil bonds with, and clings to, the black ink

In the preferred embodiment of the invention, the method may further comprise gently scrubbing the toner-adhering decorative foil-covered sticker with a solution of 91% V/V rubbing alcohol that removes toner-adhering decorative foil over the surfaces of the sticker that were not laser printed on in black ink. Gently scrubbing with the solution of 91% VN rubbing alcohol does not remove the toner-adhering decorative foil from the surfaces that were laser printed on in black ink. After this cleaning step, elements of the circuit design are therefore clear (hence the use of clear vinyl sticker), while the areas between elements of the circuit design are a highly opaque layering of black ink and reflective and opaque toner-adhering decorative foil.

In the preferred embodiment of the invention, the method may be performed in an automated work-flow process. The automated work-flow process may automatically laminate the photoresist material onto the copper sheeting. The automated work-flow process may automatically apply the clear vinyl sticker onto the surface of the photoresist material of the laminated copper sheeting. The automated work-flow process may automatically advance the sticker-covered laminated copper sheeting to a cleaning station where gentle scrubbing takes place. The automated work-flow process may automatically gently scrub away the toner-adhering decorative foil from the smooth side of the sticker. The automated work-flow process may automatically control the exposure time of the copper sheeting covered with the clear vinyl sticker, black ink, and toner-adhering decorative foil to UV or optical light. All steps that are part of the automated work-flow process may be achieved through mechanical or computer-controlled physical manipulation including, but not limited to, conveyor belts, robotic arms, and suction cups.

In one embodiment of the invention, the sticker may be made of a transparent or translucent material that allows at least some UV or other light to pass through.

In one embodiment of the invention, the method comprises gently scrubbing the toner-adhering decorative foil covered sticker with a cleaning agent, wherein the cleaning agent is any liquid that removes toner-adhering decorative foil over the surfaces of the sticker that were not laser printed on in black ink and does not remove the toner-adhering decorative foil from the surfaces that were laser printed on in black ink. This cleaning agent may be an alcohol solution containing any percentage of alcohol.

We claim:

1. A method of preparing copper sheeting for exposure to UV or optical light in the process of manufacturing flexible printed circuit boards comprising:
laminating the copper sheeting with a photoresist material;
applying a sticker onto a surface of the photoresist material of the laminated copper sheeting, wherein the sticker has a sticky side and a smooth side and is made of a transparent or translucent material, wherein the sticky side of the sticker is placed completely flush to the surface of the photoresist material of the laminated copper sheeting in order to minimize gaps between the sticker and the surface of the photoresist material of the laminated copper sheeting, and wherein the sticky side of the sticker is coated with an optically reflective glue in order to reflect incidental UV light and other light away from the gaps between the sticker and the surface of the photoresist material of the laminated copper sheeting;
laser printing, using black ink, a circuit design onto the smooth side of the sticker;
hot-laminating toner-adhering decorative foil onto the smooth, black ink covered side of the sticker; and
gently scrubbing the surface of the toner-adhering decorative foil with a cleaning agent, wherein the cleaning agent removes the toner-adhering decorative foil over surfaces of the sticker that are not covered in the black ink.

2. The method as in claim 1, wherein said transparent or translucent material is clear vinyl.

3. The method as in claim 1, wherein said cleaning agent is a solution of 91% V/V rubbing alcohol.

4. The method as in claim 1, wherein said cleaning agent is an alcohol-based solution.

5. The method as in claim 1, wherein said circuit design includes traces, lines, pads, and symbols.

6. The method as in claim 1, wherein said method or any step of said method is performed automatically as part of an automated work-flow process.
